(19) United States
(12) Patent Application Publication
(10) Pub. No.: US 2008/0037222 A1
(43) Pub. Date: Feb. 14, 2008

(54) HEAT DISSIPATION ASSEMBLY

(75) Inventors: Vikas Jha, Hillsborough, CA (US); Vassilis Argyrus Papavassiliou, Oakland, CA (US); Rajeev Bector, Saratoga, CA (US); Vishal Goenka, San Mateo, CA (US); Sailendra Padala, San Mateo, CA (US)

Correspondence Address: PAUL, HASTINGS, JANOFSKY & WALKER LLP, 875 15th Street, NW, Washington, DC, 20005, US

(73) Assignee: DDCIP Technologies, Inc.

(21) Appl. No.: 11/676,118

(22) Filed: Feb. 16, 2007

Related U.S. Application Data
(60) Provisional application No. 60/774,697, filed on Feb. 17, 2006.

(51) Int. Cl. H05K 7/20

(52) U.S. Cl. 361/709

(57) ABSTRACT

In accordance with one embodiment, the assembly includes a chassis with a board mounted to it that has one or more electronic components. Spaced apart from the board is a bridge heat sink. A heat transfer block is positioned adjacent the electronic component of the board with the heat transfer block in thermal communication with the electronic component to afford transferring of heat (e.g., conductive transfer of heat) from the electronic component to the heat transfer block. An opposite end of the heat transfer block is adjacent the bridge heat sink. The bridge heat sink has at least a portion located externally from the chassis so that the bridge heat sink (which is in thermal communication with the heat transfer block) affords the transferring of heat from the heat transfer block to an environment external to the chassis.

### CROSS REFERENCES TO RELATED APPLICATIONS

This application claims benefit to U.S. Provisional Application No. 60/774,697, filed Feb. 17, 2006 which is incorporated by reference herein in its entirety.

### TECHNICAL FIELD

Embodiments described herein relate to heat dissipaters and, more particularly, a thermally-coupled heat dissipation assembly for use with heat-generating devices such as, for example, solid state electronic components.

### BACKGROUND

Heat can have detrimental effects on solid state electronic devices if not effectively dissipated. Heat is a natural occurring by-product of solid state electronic devices because of the intimate relationship between heat and power. As a solid state device draws power and completes a task for which it is designed to accomplish, heat is generated. In some devices, the heat generated (and, therefore, subjected upon the device) may be low in comparison to the total “heat stress” that the device can stand. In other devices, however, heat can be the enemy.

Heat can be especially detrimental to the proper operation of semiconductors. For example, the heat generated by a central processing unit (CPU) and the graphics processing unit (GPU) of a computer, if not properly dissipated, can destroy the CPU or the GPU as well as other vital components of a PC computer.

As new advancements increase the speed of computer CPUs, so causes the need for more power to run the faster CPUs, and hence more heat is generated. Multi-media applications striving for high-quality media playback are also striving for quiet, reliable operation. The heat generated by an older style CPU (e.g., a 286, 386, or 486 based processor) did not typically require the use of a heat dissipater. The heat generated by these kinds of processors was typically allowed to dissipate through convection cooling (i.e., heat transfer by the natural flow of hot air from the processor). But as CPU technology advanced (such as, e.g., Pentium processors), additional cooling became needed. Typically, these faster CPUs were equipped with a heat sink mounted on top of the CPU and a fan mounted on top of the heat sink for blowing air through the heat sink fins towards the top of the CPU. An example of such a cooling device can be found in U.S. Pat. No. 5,603,374 to We. Unfortunately, such a device has many deficiencies. For example, this device relies on a single heat sink and fan assembly. While this type of configuration may be adequate for an older style processor (e.g., a 486-based processor), it is not adequate for dissipating the heat generated by Pentium-based and other faster style processors. Further, the single fan assembly in this reference does not provide any redundancy to the heat dissipation system. If the single fan fails, the cooling system will not provide the necessary cooling ability required. The result is thermal run-away of the CPU and its subsequent failure in operation. Still further, the “stacking” of a heat sink and fan on top of a processor tends to cause spacing problems when used with today's processors. This can be attributed to the large heat sinks required for today's processors. The size of the heat sink tends to be proportional to the amount of heat generated by a fast-speed processor. In other words, very fast processors require very large heat sinks.

In an effort to limit the size or profile of the heat sink, various attempts have been made in order to provide low profile heat sinks. Examples of such attempts can be found in U.S. Pat. No. 5,794,685 to Dean; U.S. Pat. No. 5,309,983 to Bailey, U.S. Pat. No. 5,615,084 to Anderson et al. and U.S. Pat. No. 5,873,406 to Hong. However, none of these prior attempts provide sufficient redundancy to guard against cooling failures or extract heat to the exterior of a PC's chassis.

Various other attempts at improving cooling include U.S. Pat. No. 5,353,863 to Yeh; U.S. Pat. No. 5,771,153 to Sheng; and U.S. Pat. No. 5,835,347 to CCU. However, each of these references describe very product specific solutions and none provide redundancy. Additional attempts are described in U.S. Pat. No. 5,457,342 to Herbst II and U.S. Pat. No. 5,706,169 to Yeh. A further attempt at providing additional heat dissipation capabilities for a CPU resulted in the development of a product produced by ComputerNerd (www.computernerd.com)—including but not limited to their FAC7BETA Heat Sink Fan combo—that utilizes a pair of heat sinks for surrounding a processor mounted on a daughter board with fans provided on the heat sink that is placed proximal to the front side die of the processor. A second heat sink is merely placed proximal to the back-side of daughter board, where the solder connections of the electrical components are located. Since 90% of all heat generated by a CPU emanates from the die area (i.e., the front-side of the CPU), the second back-side heat sink provides essentially no additional heat dissipation for the processor, since the back-side heat sink fails to communicate in any manner with the front-side heat sink.

Additional prior art may include U.S. Pat. No. 2,412,989 to Kotterman; U.S. Pat. No. 3,317,798 to Chu et al.; U.S. Pat. No. 3,749,981 to Koltuniak et al.; U.S. Pat. No. 4,449,579 to Miyazaki et al.; U.S. Pat. No. 4,557,225 to Sagues et al.; U.S. Pat. No. 5,054,545 to Ghaemian; U.S. Pat. No. 5,184,281 to Samarov et al.; U.S. Pat. No. 5,309,983 to Bailey; U.S. Pat. No. 5,353,863 to Yu; U.S. Pat. No. 5,457,342 to Herbst, II; U.S. Pat. No. 5,603,374 to Wu; U.S. Pat. No. 5,615,084 to Anderson et al.; U.S. Pat. No. 5,706,169 to Yeh; U.S. Pat. No. 5,735,340 to Mira et al.; U.S. Pat. No. 5,771,153 to Sheng; U.S. Pat. No. 5,785,116 to Wagner; U.S. Pat. No. 5,794,685 to Dean; U.S. Pat. No. 5,815,371 to Jeffries et al.; U.S. Pat. No. 5,816,319 to Kamekawa et al.; U.S. Pat. No. 5,818,694 to Daikoku et al.; U.S. Pat. No. 5,835,347 to Chu; U.S. Pat. No. 5,838,065 to Hamburgen et al.; U.S. Pat. No. 5,864,465 to Liu; U.S. Pat. No. 5,873,406 to Horng; U.S. Pat. No. 5,936,836 to Scholder; U.S. Pat. No. 5,945,736 to Rife et al.; U.S. Pat. No. 5,999,405 to Zappacosta et al.; and U.S. Pat. No. 6,101,091 to Baik.

Thus, it can be seen that an improved cooling system is needed for computer CPUs and other solid state devices that generate substantial heat.

### SUMMARY

Embodiments of a heat dissipation assembly are described. One or more heat transfer blocks are in thermal communication with a large heat sink that has an exterior face exposed to the external environment to assist in the conduction of heat away from components via the heat transfer blocks.

In accordance with one embodiment, the assembly includes a chassis with a board mounted to it that has one or more electronic components. Spaced apart from the board is a bridge heat sink. A heat transfer block is positioned adjacent to the electronic component of the board with the heat transfer block in thermal communication with the electronic component to afford transferring of heat (e.g., conductive transfer of heat) from the electronic component to the heat transfer block. An opposite end of the heat transfer block is adjacent the bridge heat sink. The bridge heat sink has at least a portion located externally from the chassis so that the bridge heat sink (which is in thermal communication with the heat transfer block) affords the transferring of heat from the heat transfer block to an environment external to the chassis.

In one embodiment, at least one of heat transfer blocks and the bridge heat sink may have a thermal conductivity of at least 200 W/mK. In another embodiment, the heat transfer block may be pressed against electronic component by the bridge heat sink. In such an embodiment, the heat transfer block can exert a force of between 0.05 and 5.0 KG per square inch against the electronic component. In one such embodiment, the heat transfer block can have a length that is greater than the defined space between the bridge heat sink and the electronic component on the board so that the heat transfer block at least pushes the electronic component and/or board away from the bridge heat sink.

In one embodiment, the board may comprise a printed circuit board. In another embodiment, the electronic component may comprise a processor (such as e.g., a CPU and/or a graphics processing unit). In such an embodiment, the heat transfer block may be positioned adjacent a die surface of the processor. In one embodiment, the heat transfer block may be positioned so that it is in actual contact with the electronic component. In some embodiments, a thermal agent may be interposed between the electronic component and the heat transfer block with the thermal agent helping to increase thermal conductivity between the electronic component and the heat transfer block. In yet another embodiment, the heat transfer block is cylindrical in shape.

In one embodiment, the heat transfer block may be coupled to the bridge heat sink. The bridge heat sink may also be coupled to the chassis. In another embodiment, the bridge heat sink may actually comprise a portion of the chassis. The bridge heat sink may have one or more outwardly extending heat dissipation fins.

In some embodiments, side gap(s) may be formed between the chassis and the board to permit passage of air therebetween. In one implementation, the side gap(s) can have a width between the chassis and the board between 0.010 inch and 0.300 inch. In a further embodiment, at least one mounting flange may be provided for mounting the chassis to a mounting surface. Spacers may also be provided for positioning between the mounting flange and the mounting surface to define an air space between the chassis and the mounting surface.

### BRIEF DESCRIPTION OF THE DRAWINGS

FIG. 1 is a schematic perspective view of one embodiment of a heat dissipation assembly;

FIG. 2 is a schematic cross sectional view of the embodiment of the heat dissipation assembly shown in FIG. 1;

FIG. 3 is a schematic top view of the embodiment of the heat dissipation assembly shown in FIG. 1;

FIG. 4 is a schematic left side view of the embodiment of the heat dissipation assembly shown in FIG. 1;

FIG. 5 is schematic right side view of the embodiment of the heat dissipation assembly shown in FIG. 1;

FIG. 6 is schematic front side view of the embodiment of the heat dissipation assembly shown in FIG. 1;

FIG. 7 is a schematic front side view of another embodiment of the heat dissipation assembly mounted to a vertical structure with ancillary convection cooling shown with the upwardly extending arrows;

FIG. 8 is a representative graph of temperature rise above ambient for an exemplary embodiment of the heat dissipation assembly;

FIG. 9 is a representative graph of thermal resistance for an exemplary embodiment of the heat dissipation assembly;

FIG. 10 is a schematic side view of an illustrative embodiment of a bridge heat sink;

FIG. 11 is a schematic cross sectional view of an illustrative embodiment of a heat dissipation assembly with an internally mounted convection fan;

FIG. 12 is a schematic top view of an illustrative embodiment of a heat dissipation assembly with an internally mounted convection fan.

### DETAILED DESCRIPTION

As set forth below, the various embodiments described herein generally provide a passive cooling system for heat dissipation.

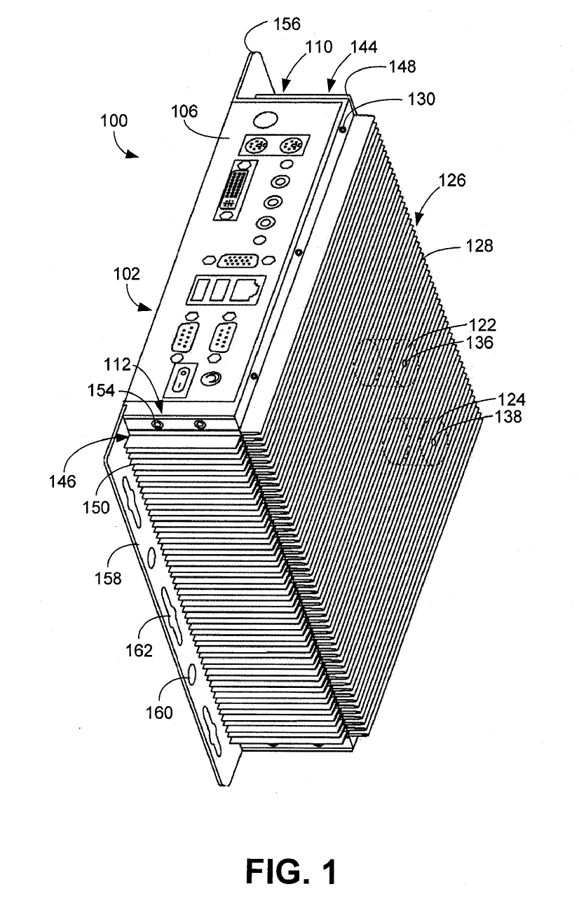

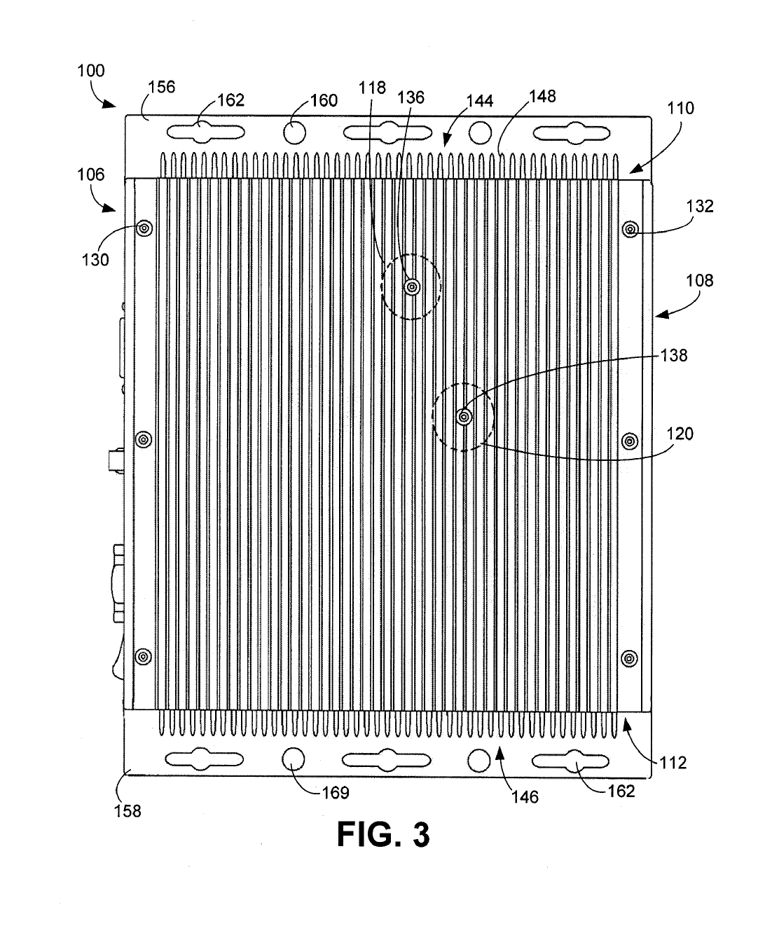

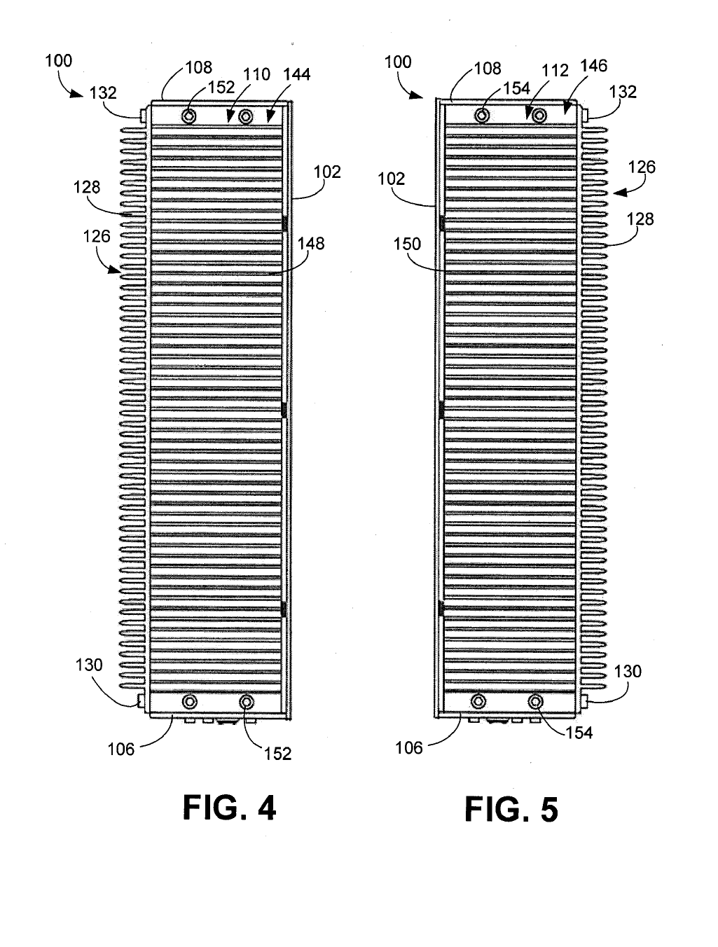

More particularly, FIGS. 1-6 illustrate an exemplary embodiment of heat dissipation assembly 100 that may be used to dissipate heat from electronic devices such as, for example, solid state electronic components. As shown in the exemplary embodiment illustrated in FIGS. 1-6, embodiments of the heat dissipation assembly may be used in conjunction with a computer chassis 102 and a printed circuit board 104 (PCB).

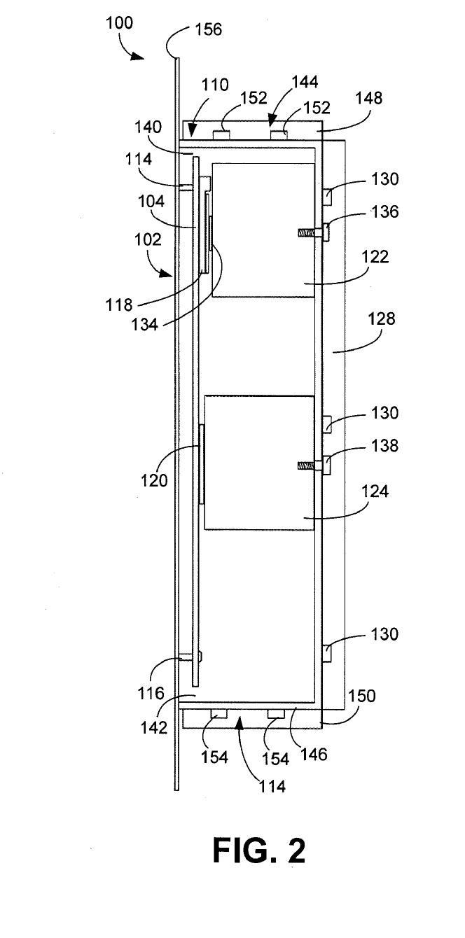

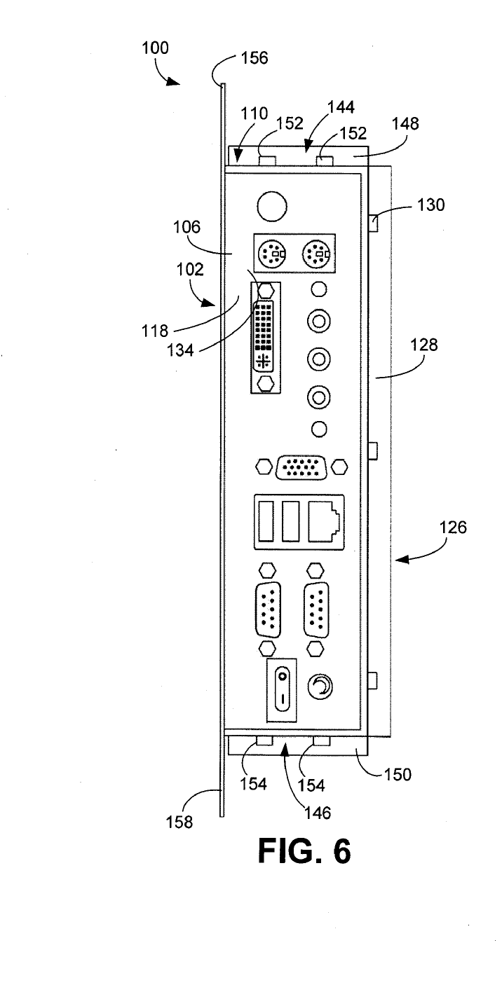

As best illustrated in FIGS. 1 and 6, the chassis 102 may include at least a front panel 106 having one or more sockets providing various inputs and outputs. The chassis 102 may also include a back panel 108 that is spaced apart from its front panel 106 so that the PCB 104 may be positioned between the front and back panels 106, 108. In addition, the chassis 102 may also include left and right side panels 110, 112 so that the periphery of the PCB 104 may be encompassed with the front, back, left and right panels of the chassis. With particular regard to the cross section shown in FIG. 2, the PCB 104 may be mounted to the chassis 102 (via, e.g., mounts 114, 116). In one embodiment, the PCB 104 may comprise a personal computer (PC) motherboard (such as, e.g., a mini-ITX form factor motherboard) having mounted to it at least one microprocessor device 118 such as, for example, a central processing unit (CPU) (which may also be referred to as the primary microprocessor) and possibly even one or more additional secondary microprocessors or other electronic components 120 (e.g., a graphics processor unit (GPU)). In a typical embodiment, the microprocessors (especially the primary microprocessor) may often be mounted to the PCB 104 through the use of an intermediary socket (such as, e.g., an Intel Socket 479 and the like). In other embodiments, the primary microprocessor and/or the secondary microprocessor(s) may be soldered to the PCB.

Typically, when in use, the primary and secondary microprocessors 118, 120 are capable of generating substantial amounts of heat for which the cooling solution afforded by the heat dissipation assembly may be used in order to avoid runaway overheating and consequent risk of damage to these microprocessors (as well as other devices mounted to (or in proximity with) the PCB 104 such as hard drives, system memory, resistors, transformers, and other electronic devices installed inside the chassis). With the cooling solutions offered by the embodiments described herein, the area inside the chassis may remain at an air temperature sufficiently cool enough so that components inside the chassis and/or on the PCB can operate well within their specified maximum operating temperature without necessarily requiring active cooling solutions such as electric fans that generate noise and can be a point of failure (i.e., they can break down).

In general, the heat dissipation assembly 100 may include one or more heat transfer blocks 122, 124 and a bridge heat sink 126 (also referred as the “bridge”). Preferably, at least one heat transfer block 122, 124 is provided for each microprocessor 118, 120 on the PCB 104 (e.g., two heat transfer blocks are included in the embodiment depicted in FIGS. 1-6). As best shown in FIG. 2, one end of each heat transfer block 122, 124 is in contact with or in near proximity with its associated microprocessor 118, 120 to afford thermal coupling between each heat transfer block/microprocessor pair and thereby permit transfer of heat from the microprocessor to the heat transfer block. The other end of each heat transfer block 122, 124 may be coupled to the bridge heat sink 126 so that the heat transfer block is thermally coupled to the bridge heat sink. Through this arrangement, heat from the microprocessor(s) 118, 120 may be transferred through the heat transfer block(s) 122, 124 to the bridge heat 126 sink thereby facilitating the evacuation of heat from the microprocessor(s).

The bridge heat sink 126 is intended to dissipate the heat generated by the microprocessors 118, 120 (and other components of the PCB 104) to the outside of the chassis 102. The bridge heat sink 126 may be mounted to the chassis 102 and, in some embodiments, may even serve as part (or all) of the chassis 102 (e.g., as a top panel of the chassis that covers the PCB 104). The bridge heat sink 126 may include a plurality of outwardly extending cooling fins 128 to enhance its heat dissipation capabilities. In one embodiment, the bridge heat sink 126 may be secured rigidly to the chassis 102 by coupling the bridge heat sink 126 to the chassis 102 with, for example, a plurality of fasteners (e.g., screws, rivets, and the like). In the embodiment shown in FIGS. 1-6, the bridge heat sink may be secured to the front and back panels of the chassis by such fasteners 130,132 along front and back side edge regions of the bridge heat sink 126.

When two or more heat transfer blocks 122, 124 are provided, the heat transfer blocks 122, 124 may be arranged so that they are spaced apart from one another and, optionally, substantially parallel to each other. To enhance the thermal conductivity between the heat transfer blocks 122, 124 and the microprocessors 118, 120, a heat sink paste, heat tape, or other thermal bonding agent/compound 134 may be interposed between the heat transfer blocks 122, 124 and the microprocessors 118, 120 to lower the thermal resistance between the microprocessor and the heat transfer blocks. In some embodiments, a heat paste 134 may be preferable in order to allow for easier disassembly and reassembly of the assembly 100. As best shown in FIG. 2, each heat transfer block 122, 124 may be coupled to the bridge heat sink 126 by a fastener 136, 138 such as a screw, rivet and/or adhesive between the bridge heat sink and the heat transfer block. As further option, a heat sink paste, heat tape, thermal bonding epoxy or other thermal bonding agent/compound may be interposed between the heat transfer blocks 122, 124 and the bridge heat sink 126 to further enhance the thermal conductivity between them.

As shown in the drawings, in one embodiment, while the heat transfer block(s) 122, 124 may be any shape, a cylindrical shape for the heat transfer block(s) 122, 124 may be preferred this configuration has less surface-to-air contact than a square or rectangular bar shaped block or even one with radial fins and thereby affords less heat dissipation inside the chassis and greater heat transfer to the bridge heat sink 126 (and consequent more heat dissipation to the outside air). In an illustrative embodiment, each heat transfer block 122, 124 may comprise a solid length of thermally conductive material that has a thermal conductivity greater than 200 W/mK.

While some prior art may involve a heat sink that attaches directly to the microprocessor or the microprocessor socket or where the clips and/or fasteners are used to secure a heat sink (with or without an integrated cooling fan) directly to a PCB on which the microprocessor is mounted, no fasteners are necessary between a microprocessor 118, 120 and a heat transfer blocks 122, 124 in the embodiments described herein. Instead, when assembling some embodiments of the assembly described herein, the heat transfer blocks 122, 124 may be first coupled to the bridge heat sink 126 which is then positioned over the PCB 104 and chassis 102 so that the heat transfer blocks 122, 124 are positioned to rest squarely and firmly on a die surfaces of the corresponding microprocessors 118, 120 when the bridge heat sink 126 is coupled to the chassis 102. Before the heat transfer blocks 122, 124 are coupled to the bridge heat sink 126 and/or before positioning of the heat transfer blocks 122, 124 and bridge heat sink 126 over the PCB 104 and chassis 102, the thermal agent/compound 134 such as a heat sink compound, heat tape, or thermal bonding epoxy may be placed between the heat blocks and the bridge heat sink and on the surfaces of the heat blocks and microprocessors that are to be positioned in contact with one another (so that thermal agent(s) are located between the heat transfer blocks, microprocessors and bridge heat sink once the assembly is assembled.

Embodiments may also employ a method of engineering a firm pressure between the assembly and the microprocessor(s). For example, the PCB 104 may be mounted into the chassis 102. Prior to attaching the heat transfer blocks to the bridge heat sink, the bridge heat sink 126 may be mounted (e.g., by fasteners 130, 132) to the chassis 102 into its proximal final position with the bottom face of the bridge heat sink 126 being parallel to the die surface(s) of the microprocessor(s) 118,120. The space or gap separating the die surface(s) of the microprocessor(s) 118, 120 and the bottom face of the bridge heat sink 126 can then be measured for shortest distance between them. The heat transfer blocks 122, 124 may then cut (or sized) so that the top and the bottom faces of each heat transfer block 122, 124 are parallel and their height is nominally greater than the space it fills between the associated microprocessor die face 118, 120 and the bottom face of the bridge heat sink 122, 124. By making the heat transfer blocks 122, 124 slightly longer than the distance between the die faces of their associated microprocessors 118, 120 and the bottom face of the bridge heat sink 126, the extra length (or height) is absorbed by the PCB 104 with the PCB 104 acting as a spring whose potential energy exerts a persistent upwards force towards the bottom face of bridge heat sink 126 so that the microprocessors 118, 120 are pressed against their respective heat transfer blocks 122, 124. This pressure or biased arrangement helps to improve the heat transferring ability between the microprocessors 118, 120 and the heat transfer blocks 122, 124 by helping to ensure that the microprocessors 118, 120 are in contact with the heat transfer blocks 122, 124. In an illustrative embodiment, the heat transfer blocks 122, 124 may be cut so that they are between 0.008 inch and 0.012 inch longer than the space or gap between the closest or top face of their associated microprocessor and the bottom face of the bridge heat sink 126. In preferred embodiment, the length of the heat transfer blocks 122, 124 may 0.010 inch longer than the space or gap between the closest or top face of their associated microprocessor and the bottom face of the bridge heat sink. This length has been found to create a positive pressure/force of approximately 1.5 KG pounds per square inch between the heat transfer block 122, 124 and the microprocessor die surface 118, 120.

For many applications, the embodiments described above may be sufficient for providing a passive cooling system. However, the features described in the following additional embodiments may also be implemented as further options and permutations of the heat sink assembly 100.

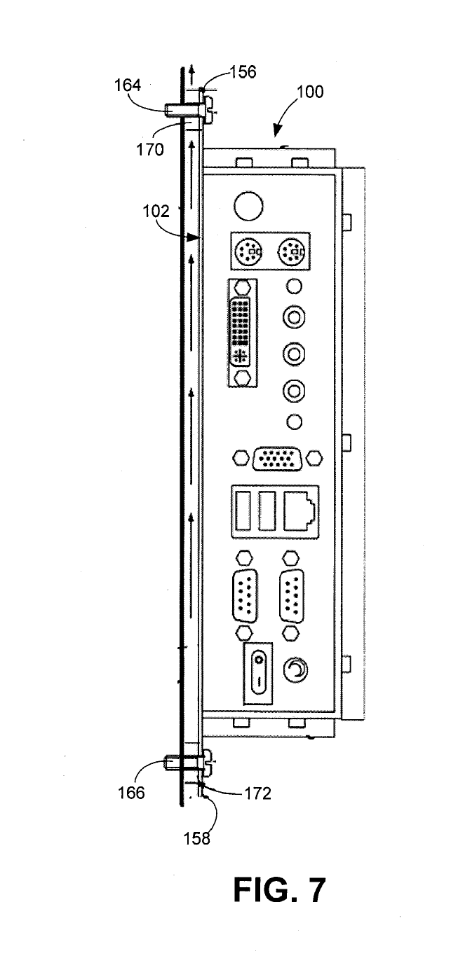

For example, one or more gaps 140, 142 may be left between one or more side panels of the chassis 102 and the adjacent edge(s) of the PCB 104 to provide convection slots to let air pass through the gap(s). As best shown in FIG. 2, in one illustrative embodiment, such gaps 140, 142 may be formed between the left and right panels of the chassis 102 and the corresponding adjacent (left and right) edges of the PCB 104. In one preferred embodiment, the spacing of such gaps 140, 142 may measure 0.080 inch wide by 6.8 inches long between opposing side panels of the chassis 102 and the corresponding edges of the PCB 104. These gaps 140, 142 may also be interspersed by grounding points to help reduce radio frequency interference. With reference to FIG. 7, when the chassis 102 is mounted in its normal orientation with its left panel facing upwards, a natural convection current (represented by the upwardly extending arrows) may help to dissipate a portion of the heat that might otherwise accumulate inside the chassis (and thereby potentially interfere with the normal operation of the components of the PCB).

In another embodiment, the right and left side panels of the chassis 102 may be replaced (or have incorporated into them—i.e., comprise part of or all of the right and left side panels of the chassis) corresponding left and right side heat sinks 144, 146 each having a plurality of outwardly extending fins 148, 150 for enhancing heat dissipation with the external air. These side heat sinks may be constructed so that they are integral with the bridge heat sink. The side heat sinks 144, 146 may also be coupled to the chassis 102 using fasteners 152, 154 such as, for example, screws and/or rivets.

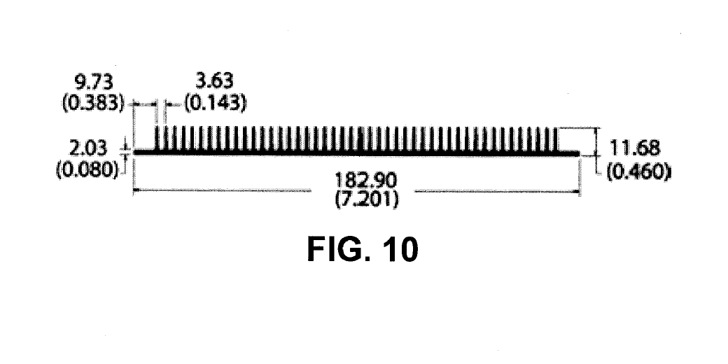

In one embodiment, the bridge heat sink 126 and/or the side heat sinks 144, 146 may be made using an extrusion with aluminum cooling fins such as Avid Thermalloy part number 68855 with dimensions and natural convection properties set forth below in Table 1 and in FIG. 10.

TABLE 1

| | | Thermal | | | | | |
|---|---|---|---|---|---|---|---|
| | | Resistance | | | | | |
| | Part | ° C./W at 3 | Width | Height | Surface | Weight | Part |
| | Number | in length | in | in | Area in | lb/ft | Class |
| 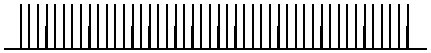 | 68855 | 1.51 | 7.20 | 0.46 | 46.3 | 1.70 | B |

In a further embodiment, the chassis 102 may be constructed from a material that has a thermal conductivity greater than 200 W/mK. Such a material would help conduct at least a portion of the heat that would otherwise accumulate inside the chassis 102. In a preferred embodiment, the chassis 102 may be composed from a material such as, for example, aluminum and, even more preferably, an aluminum having a thermal conductivity of 205 W/mK.

In one illustrative embodiment, the heat transfer blocks 122, 124 may also be constructed from a material having a thermal conductivity greater than 200 W/mK. In a preferred embodiment, the heat transfer blocks 122, 124 may be constructed from an aluminum, and even more preferably, an aluminum having a thermal conductivity of 205 W/mK, and fabricated from round or square bar aluminum stock.

In another embodiment, the chassis 102 may have a plurality of mounting flanges 156, 158 located along the perimeter of the chassis. The mounting flanges 156, 158 may include a plurality of holes (e.g., holes 160, 162) are drilled along their lengths so that fasteners 164,166 (e.g., screws, nails, etc.) may be extended through each hold to couple the chassis 102 to a mounting structure or surface 168 such as, for example, a wall, a mount, a desktop or countertop, the underside of a cabinet, an even to a flat panel television or display. Washer-shaped spacer inserts 170, 172 may also be provided to stand off the chassis 102 from the mounting surface 168 to leave an air space between the underside of the PC chassis 102 and the mounting surface 168. The resulting airspace helps allow natural air convection along the under surface of the chassis 102 in order to further assist in the dissipation of heat from inside the chassis 102.

Thus, the embodiments described herein may be used to afford an improved heat dissipation system for computer CPUs that can also be used with a plurality of different processors, including, but not limited to other microprocessors mounted onto the same motherboard as the CPU and socketed directly to a main board. The system may also allow the use of a multitude of thermally-bridged passive cooling elements surrounding each microprocessor. Secondary passive cooling elements may also be employed which are not susceptible to failure and will re-direct heat away from the CPU and thereby help avoid thermal runaway of the processor. Using embodiments of the system disclosed herein, may provide a means for conducting heat generated by microprocessors away from the interior of the PC chassis assembly through a passive transferring method that directly evacuates generated heat to an exterior component of the PC chassis assembly where it can freely dissipate to the outside air. The highly conductive heat transfer blocks may even be positioned employed in a spaced and parallel relationship while also being thermally coupled to an additional bridge member heat sink. The thermally coupled heat dissipation system may provide heat dissipation sufficient to operate the main board microprocessor devices within their normal operating temperature specifications without necessarily needing internally or externally mounted cooling fans.

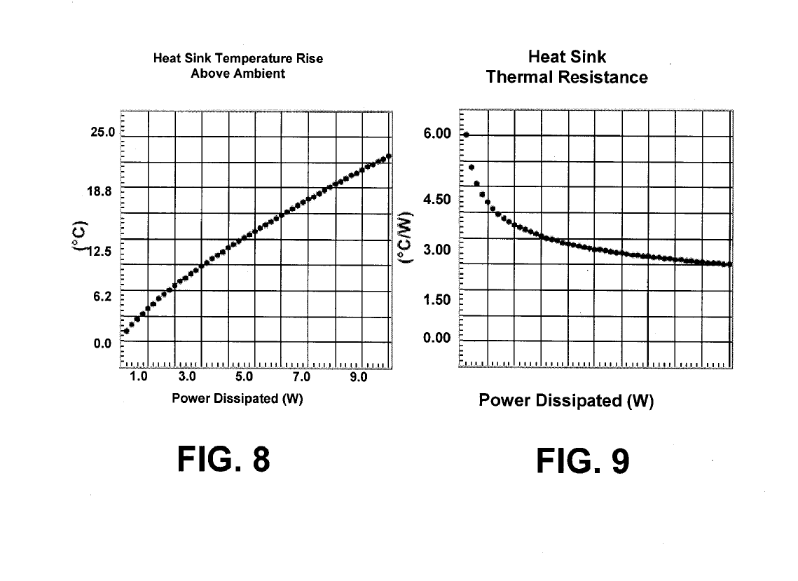

FIGS. 8 and 9 show representative graphs of an illustrative embodiment of the heat dissipation assembly. More particularly, FIG. 8. is a graph showing temperature rise above ambient for an exemplary embodiment of the heat dissipation assembly and FIG. 9 is a graph showing thermal resistance for an exemplary embodiment of the heat dissipation assembly.

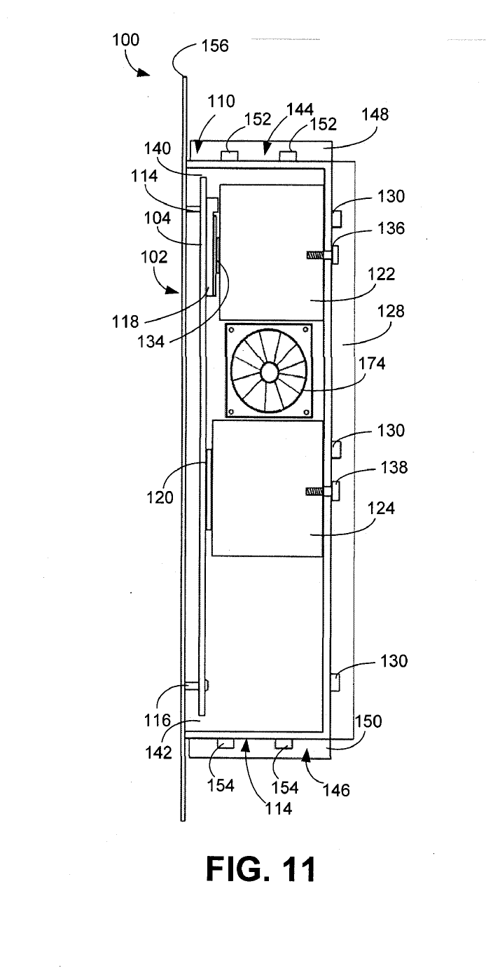

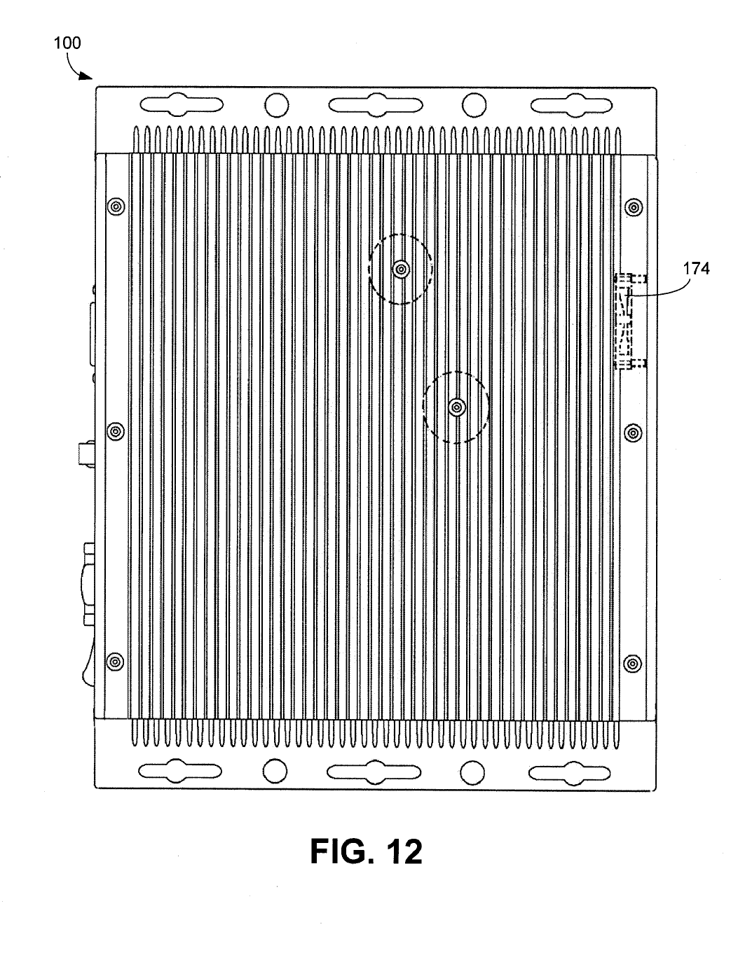

As an option, an embodiment of the system may further include an internally mounted convection fan. FIGS. 11 and 12 show a representative embodiment of the heat dissipation assembly with such an internally mounted convection fan 174. The fan 174 may be mounted to an internal surface of the chassis in order to assist in the circulating of the superheated air generated inside the chassis to thereby further improve the heat dissipation characteristics of the system. In one such embodiment the convection fan may be mounted on standoffs so as to leave a preferred air gap of 0.120″ between the fan and the chassis wall. The fan 174 may intake superheated air from the interior airspace closest to the heat transfer blocks and push or force the heated air against the interior surface of the chassis and then out through the air gaps created by the standoffs (in all directions), in a manner that can supplement convection thereby causing a greater percentage of top heat sink, side heat sinks, and chassis to absorb heat from the superheated air that would otherwise stagnate and accumulate in the immediate proximity of the heat transfer blocks (and thereby allow a larger percentage of the apparatus to dissipate heat). In some embodiments, the use of such a fan has been found to drop the internal operating temperatures three to five degrees centigrade.

In another optional “sealed system” embodiment where a convection fan is employed, the air gap between the side heat sinks and the chassis may be eliminated to effectively prevent intrusion of outside air and contaminants such as dust and particulate to enter the internal region of the apparatus. In such an embodiment, the convection fan does not accumulate particulate that would eventually destroy fan bearings because there is no exhaust fan employed in the apparatus and effectively no exchange of inside and contaminated outside air.

As previously mentioned, this application claims benefit to U.S. Provisional Application No. 60/774,697, filed Feb. 17, 2006 which is incorporated by reference herein in its entirety.

While various embodiments have been described above, it should be understood that they have been presented by way of example only, and not limitation. Thus, the breadth and scope of a preferred embodiment should not be limited by any of the above described exemplary embodiments, but should be defined only in accordance with the following claims and their equivalents.

What is claimed:

1. A system, comprising:
a chassis;
a board mounted to the chassis and having an electronic component;
a heat transfer block adjacent the electronic component, the heat transfer block in thermal communication with the electronic component to afford transferring of heat from the electronic component to the heat transfer block; and
a bridge heat sink adjacent to the heat transfer block and having at least a portion located externally from the chassis, the bridge heat sink being in thermal communication with the heat transfer block to afford transferring of heat from the heat transfer block to an environment external to the chassis.

2. The system of claim 1, wherein at least one of heat transfer block and the bridge heat sink have a thermal conductivity of at least 200 W/mK.

3. The system of claim 1, wherein the heat transfer block is pressed against electronic component by the bridge heat sink.

4. The system of claim 3, wherein the heat transfer block exerts a force of between 0.05 and 5.0 KG per square inch against the electronic component.

5. The system of claim 1, wherein the electronic component comprises a processor.

6. The system of claim 5, wherein the heat transfer block is adjacent a die surface of the processor.

7. The system of claim 1, wherein the heat transfer block is in contact with the electronic component.

8. The system of claim 1, wherein the heat transfer block is coupled to the bridge heat sink.

9. The system of claim 1, wherein the bridge heat sink is coupled to the chassis.

10. The system of claim 1, wherein the bridge heat sink comprises a portion of the chassis.

11. The system of claim 1, wherein the bridge heat sink has at least one heat dissipation fin extending away from the chassis.

12. The system of claim 1, wherein the board comprises a printed circuit board.

13. The system of claim 1, further comprising a thermal agent interposed between the electronic component and the heat transfer block, the thermal agent increasing thermal conductivity between the electronic component and the heat transfer block

14. The system of claim 1, wherein the heat transfer block is cylindrical in shape.

15. The system of claim 1, further comprising at least one side gap being formed between the chassis and the board to permit passage of air therebetween.

16. The system of claim 15, wherein the at least one side gap has a width between the chassis and the board between 0.010 inch and 0.300 inch.

17. The system of claim 1, further comprising at least one mounting flange for mounting the chassis to a mounting surface.

18. The system of claim 17, further comprising a spacer for positioning between the mounting flange and the mounting surface to define an air space between the chassis and the mounting surface.

19. The system of claim 1, wherein a space is defined between the electronic component and the bridge heat sink, the heat transfer block has a length greater than the defined space so that the heat transfer block at least pushes the electronic component away from the bridge heat sink.

20. A system, comprising:
a chassis comprising at least a bottom plate;
a printed circuit board mounted to the chassis and spaced apart from the bottom plate, the printed circuit board having at least a plurality of processor components, each processor component having a die surface;
for each processor component, a heat transfer block having a die end abutting the die surface of the corresponding processor component with a thermal agent interposed therebetween for enhancing the transfer of heat;
a bridge heat sink coupled to each heat transfer block to permit transfer of heat therebetween;
a pair of side heat sinks coupled to the bridge heat sink;
the bridge heat sink and the side heat sinks each having a plurality of outwardly extending heat dissipating fins, wherein the bridge heat sink and the side heat sinks comprise at least a portion of the chassis.
